(19) United States
(12) Patent Application Publication
(10) Pub. No.: US 2014/0252355 A1
(43) Pub. Date: Sep. 11, 2014

(54) SEMICONDUCTOR DEVICE AND METHOD FOR PRODUCING SAME

(71) Applicant: Sharp Kabushiki Kaisha, Osaka (JP)

(72) Inventors: Sumio Katoh, Osaka (JP); Makoto Nakazawa, Osaka (JP)

(73) Assignee: SHARP KABUSHIKI KAISHA, Osaka (JP)

(21) Appl. No.: 14/352,931

(22) PCT Filed: Oct. 16, 2012
(86) PCT No.: PCT/JP2012/076663

§ 371 Date: Apr. 18, 2014

(30) Foreign Application Priority Data
Oct. 21, 2011 (JP) 2011-231902

(51) Int. Cl. H01L 29/786; H01L 21/477; H01L 27/12; H01L 29/66

(52) U.S. Cl. CPC H01L 29/7869; H01L 29/66969; H01L 21/477; H01L 27/1225
USPC 257/43; 438/104

(57) ABSTRACT

The semiconductor device (100A) according to the present invention has a thin film transistor (10A1) supported on a substrate; the thin film transistor (10A1) has an oxide semiconductor layer (5a1), a gate electrode (3a1), a source electrode (8a1), a drain electrode (9a1), and a metal oxide layer (6a, 7a) formed between the source electrode (8a1) and the oxide semiconductor layer (5a1) and/or between the drain electrode (9a1) and the oxide semiconductor layer (5a1); the metal oxide layer (6a, 7a) contains a metallic element included in the source electrode (8a1) and/or the drain electrode (9a1); and the thickness T1 of the oxide semiconductor layer, the thickness T2 of the metal oxide layer, and the distance D between the source electrode (8a1) and the drain electrode (9a1) satisfy the relationship D≧1.56×(T2/T1)+0.75.

### TECHNICAL FIELD

The present invention relates to a semiconductor device formed using an oxide semiconductor, and to a method of manufacturing the semiconductor device.

### BACKGROUND ART

An active matrix substrate used in liquid crystal display devices and the like has a switching element such as a thin-film transistor (hereinafter, “TFT”) in each pixel. Conventionally, a TFT with an amorphous silicon film as an active layer (hereinafter, “amorphous silicon TFT”) or a TFT with a polycrystalline silicon film as an active layer (hereinafter, “polycrystalline silicon TFT”) has been widely used as such a switching element.

The use of an oxide semiconductor as the material of the TFT active layer, instead of amorphous silicon or polycrystalline silicon, has been recently proposed. Such a TFT is referred to as an “oxide semiconductor TFT.” Oxide semiconductors have a higher mobility than amorphous silicon. Therefore, the oxide semiconductor TFT can operate at a faster speed than the amorphous silicon TFT. Furthermore, the oxide semiconductor film is formed with a process that is simpler than for the polycrystalline silicon film, and thus, the oxide semiconductor film can be applied to devices requiring a large area.

An oxide semiconductor TFT with a bottom-gate structure is disclosed in Patent Document 1. In the oxide semiconductor TFT disclosed in Patent Document 1, the contact state between the oxide semiconductor layer and the source and drain electrodes is improved, thus reducing leakage current and improving carrier mobility.

### RELATED ART DOCUMENT

### Patent Document

Patent Document 1: Japanese Patent Application Laid-Open Publication No. 2008-219008

### SUMMARY OF THE INVENTION

### Problems to be Solved by the Invention

Oxide semiconductors do not have sufficient heat resistance, and as a result, during heat treatment (annealing) during the TFT manufacturing process, oxygen leaves the oxide semiconductor causing lattice defects. As a result of this lattice defect, changes in characteristics (changes in threshold voltage (Vth), for example) due to electrical stress occur in the oxide semiconductor TFTs. By performing high temperature annealing (250° C. to 300° C., for example) after the TFTs have been formed, oxygen can be provided to locations in the oxide semiconductor layer where there are lattice defects in order to repair the lattice defects, thus mitigating changes in characteristics in the TFTs due to electrical stress.

On the other hand, if high temperature annealing is performed to repair the lattice defects, the source and drain electrodes of the TFTs take oxygen from the oxide semiconductor layer, causing a metal oxide layer to be formed between the source and drain electrodes and the oxide semiconductor layer. If oxygen is removed from the oxide semiconductor layer, this causes an increase in OFF current. FIG. 17 is a graph for describing the relation between the distance between each source and drain electrode and the OFF current at each annealing temperature. In FIG. 17, the line S1 shows a relation between the distance between the source and drain electrode and the OFF current when the annealing temperature is 250° C. The line S2 shows a relation between the distance between the source and drain electrode and the OFF current when the annealing temperature is 300° C. The line S3 shows a relation between the distance between the source and drain electrode and the OFF current when the annealing temperature is 350° C.

As can be seen from FIG. 17, the higher the annealing temperature is, the greater the minimum distance is between the source and drain electrodes in order for the OFF current to be 1 p(1×10⁻¹²)A or less. Thus, in order for the OFF current not to increase (in order for it to remain at 1 pA or less), a TFT with a large distance between the source and drain electrodes has been used. However, if such TFTs are used in liquid crystal display devices, for example, then the aperture ratio of the pixels decreases and the area of the frame region, which is located in the periphery of the display region and does not contribute to display, becomes large.

Embodiments of the present invention take into account this situation, and an object thereof is to provide a semiconductor device with good TFT characteristics without an increase in size of the TFTs.

### Means for Solving the Problems

A semiconductor device according to an embodiment of the present invention includes a substrate and thin film transistors supported by the substrate, wherein the thin film transistors each include an oxide semiconductor layer, a gate electrode, a source electrode, a drain electrode, and a metal oxide layer formed between at least either of the source electrode and the oxide semiconductor layer, or the drain electrode and the oxide semiconductor layer, wherein the oxide semiconductor layer includes a metal element that is included in at least one of the source electrode and the drain electrode, and wherein a thickness T1 of the oxide semiconductor layer, a thickness T2 of the metal oxide layer, and a distance D between the source electrode and the drain electrode satisfy D≧1.56×(T2/T1)+0.75.

In an embodiment, the thickness T1 of the oxide semiconductor layer and the thickness T2 of the metal oxide layer further satisfy 0.21≦(T2/T1)≦0.57.

A semiconductor device according to another embodiment of the present invention includes a substrate and thin film transistors supported by the substrate, wherein the thin film transistors each include an oxide semiconductor layer, a gate electrode, a source electrode, a drain electrode, and a metal oxide layer formed between at least either of the source electrode and the oxide semiconductor layer, or the drain electrode and the oxide semiconductor layer, wherein the oxide semiconductor layer includes a metal element that is included in at least one of the source electrode and the drain electrode, and wherein a thickness T1 of the oxide semiconductor layer and a thickness T2 of the metal oxide layer satisfy 0.21≦(T2/T1)≦0.57.

In an embodiment, the semiconductor device further includes an etching stopper layer formed so as to cover a channel region of the oxide semiconductor layer.

In an embodiment, in the semiconductor device, the metal oxide layers are formed on the oxide semiconductor layer and the source electrode and the drain electrode are formed on the metal oxide layers.

In an embodiment, the semiconductor device further includes an auxiliary capacitance unit, wherein the auxiliary capacitance unit includes: a gate portion formed of the same conductive film as a conductive film from which the gate electrode is formed; a gate insulating film formed on the gate portion; another oxide semiconductor layer formed on the gate insulating film; another metal oxide layer formed on the another oxide semiconductor layer; and the drain electrode formed on the another metal oxide layer.

In an embodiment, the metal element is titanium, aluminum, chromium, copper, tantalum, molybdenum, or tungsten.

In an embodiment, the oxide semiconductor layer and the another oxide semiconductor layer include an In—Ga—Zn—O-type semiconductor.

A method of manufacturing a semiconductor device according to an embodiment of the present invention includes: (A) forming a gate electrode on a substrate; (B) forming a gate insulating film so as to cover the gate electrode; (C) forming an oxide semiconductor layer on the gate insulating film; (D) forming a source electrode and a drain electrode so as to be in contact with the oxide semiconductor layer; (E) forming a protective film so as to cover the source electrode and the drain electrode; and (F) forming a metal oxide layer on at least one of an area between the source electrode and the oxide semiconductor layer and an area between the drain electrode and the oxide semiconductor layer, by performing annealing, wherein a thickness T1 of the oxide semiconductor layer, a thickness T2 of the metal oxide layer, and a distance D between the source electrode and the drain electrode satisfy D≧1.56×(T2/T1)+0.75.

In an embodiment, the thickness T1 of the oxide semiconductor layer and the thickness T2 of the metal oxide layer further satisfy 0.21≦(T2/T1)≦0.57.

A method of manufacturing a semiconductor device according to another embodiment of the present invention includes: (A) forming a gate electrode on a substrate; (B) forming a gate insulating film so as to cover the gate electrode; (C) forming an oxide semiconductor layer on the gate insulating film; (D) forming a source electrode and a drain electrode so as to be in contact with the oxide semiconductor layer; (E) forming a protective film so as to cover the source electrode and the drain electrode; and (F) forming a metal oxide layer on at least one of an area between the source electrode and the oxide semiconductor layer and an area between the drain electrode and the oxide semiconductor layer, by performing annealing, wherein a thickness T1 of the oxide semiconductor layer and a thickness T2 of the metal oxide layer satisfy 0.21≦(T2/T1)≦0.57.

In an embodiment, the method of manufacturing a semiconductor device further includes, between the step (C) and the step (D), forming an etching stopper layer covering a portion of the oxide semiconductor layer to be a channel region.

In an embodiment, the step (A) includes forming, on the substrate, a gate portion of the same conductive film as a conductive film by which the gate electrode is formed, the step (C) includes forming another oxide semiconductor layer formed so as to overlap the gate portion across the gate insulating film, the step (E) includes forming the drain electrode so as to be in contact with the another oxide semiconductor layer, and the step (F) includes forming another metal oxide layer between the another oxide semiconductor layer and the drain electrode.

A method of manufacturing a semiconductor device according to yet another embodiment of the present invention includes: (A) forming a gate electrode on a substrate; (B) forming a gate insulating film so as to cover the gate electrode; (C) forming a source electrode and a drain electrode on the gate insulating film; (D) forming an oxide semiconductor layer so as to be in contact with the source electrode and the drain electrode; (E) forming a protective film so as to cover the source electrode and the drain electrode; and (F) forming a metal oxide layer on at least one of an area between the source electrode and the oxide semiconductor layer and an area between the drain electrode and the oxide semiconductor layer, by performing annealing, wherein a thickness T1 of the oxide semiconductor layer, a thickness T2 of the metal oxide layer, and a distance D between the source electrode and the drain electrode satisfy D≧1.56×(T2/T1)+0.75.

In an embodiment, the thickness T1 of the oxide semiconductor layer and the thickness T2 of the metal oxide layer further satisfy 0.21≦(T2/T1)≦0.57.

A method of manufacturing a semiconductor device according to yet another embodiment of the present invention includes: (A) forming a gate electrode on a substrate; (B) forming a gate insulating film so as to cover the gate electrode; (C) forming a source electrode and a drain electrode on the gate insulating film; (D) forming an oxide semiconductor layer so as to be in contact with the source electrode and the drain electrode; (E) forming a protective film so as to cover the source electrode and the drain electrode; and (F) forming a metal oxide layer on at least one of an area between the source electrode and the oxide semiconductor layer and an area between the drain electrode and the oxide semiconductor layer, by performing annealing, wherein a thickness T1 of the oxide semiconductor layer and a thickness T2 of the metal oxide layer satisfy 0.21≦(T2/T1)≦0.57.

### Effects of the Invention

According to an embodiment of the present invention, it is possible to provide a semiconductor device with good TFT characteristics without an increase in size of the TFTs.

### BRIEF DESCRIPTION OF THE DRAWINGS

FIGS. 1(a) and 1(b) are schematic cross-sectional views of a semiconductor device 100A of the present embodiment along the line I-I′ and the line II-II′ of FIG. 1(c), and FIG. 1(c) is a schematic plan view of the semiconductor device 100A.

FIG. 2(a) is a schematic plan view showing channel areas of TFTs 10A1 and 10A2, and FIG. 2(b) is a graph showing a relation between X (thickness of metal oxide layer/thickness of oxide semiconductor layer), and a time required for an OFF current of a TFT (temperature: 60°, illuminance: 5401 x, Vg=−15V, Vs=0V, Vd=10V) to exceed 1 pA due to D (distance between source and drain electrodes) and electrical stress (temperature: 60°, illuminance: 5401 x, Vg=−15V, Vs=Vd=0V).

FIG. 3(a) is a schematic cross-sectional view of a TFT 200 of a comparison example, FIGS. 3(b) and 3(c) are schematic cross-sectional views of the TFT 10A1, and FIG. 3(d) is a schematic cross-sectional view of the TFT 10A2.

FIGS. 4(a) to 4(c) schematically show respective steps of one example of a method of manufacturing the semiconductor device 100A.

FIGS. 5(a) to 5(c) schematically show respective steps of one example of a method of manufacturing the semiconductor device 100A.

FIGS. 6(a) to 6(c) schematically show respective steps of one example of a method of manufacturing the semiconductor device 100A.

FIGS. 7(a) and 7(b) schematically show respective steps of one example of a method of manufacturing the semiconductor device 100A.

FIGS. 8(a) and 8(b) are schematic cross-sectional views of a semiconductor device 100B of another embodiment along the line III-III′ and the line IV-IV′ of FIG. 8(c), and FIG. 8(c) is a schematic plan view of the semiconductor device 100B.

FIGS. 9(a) to 9(c) schematically show respective steps of one example of a method of manufacturing the semiconductor device 100B.

FIGS. 10(a) to 10(c) schematically show respective steps of one example of a method of manufacturing the semiconductor device 100B.

FIGS. 11(a) to 11(c) schematically show respective steps of one example of a method of manufacturing the semiconductor device 100B.

FIGS. 12(a) and 12(b) schematically show respective steps of one example of a method of manufacturing the semiconductor device 100B.

FIGS. 13(a) and 13(b) are schematic cross-sectional views of a semiconductor device 100C of another embodiment along the line V-V′ and the line VI-VI′ of FIG. 13(c), and FIG. 13(c) is a schematic plan view of the semiconductor device 100C.

FIGS. 14(a) to 14(c) schematically show respective steps of one example of a method of manufacturing the semiconductor device 100C.

FIGS. 15(a) to 15(c) schematically show respective steps of one example of a method of manufacturing the semiconductor device 100C.

FIGS. 16(a) and 16(b) schematically show respective steps of one example of a method of manufacturing the semiconductor device 100C.

FIG. 17 is a graph for describing the relation between the distance between each source and drain electrode and the OFF current at each annealing temperature.

### DETAILED DESCRIPTION OF EMBODIMENTS

Below, an embodiment of a semiconductor device of the present invention will be explained with reference to figures. The semiconductor device of the present embodiment is provided with a thin-film transistor (oxide semiconductor TFT) that has an active layer made of an oxide semiconductor. The semiconductor device of the present embodiment simply needs to include an oxide semiconductor TFT, and includes a wide range of active matrix substrates, various types of display devices, electronic devices, and the like.

A TFT substrate having an oxide semiconductor TFT as a switching element will be explained as an example. The TFT substrate of the present embodiment can be suitably used in a liquid crystal display device.

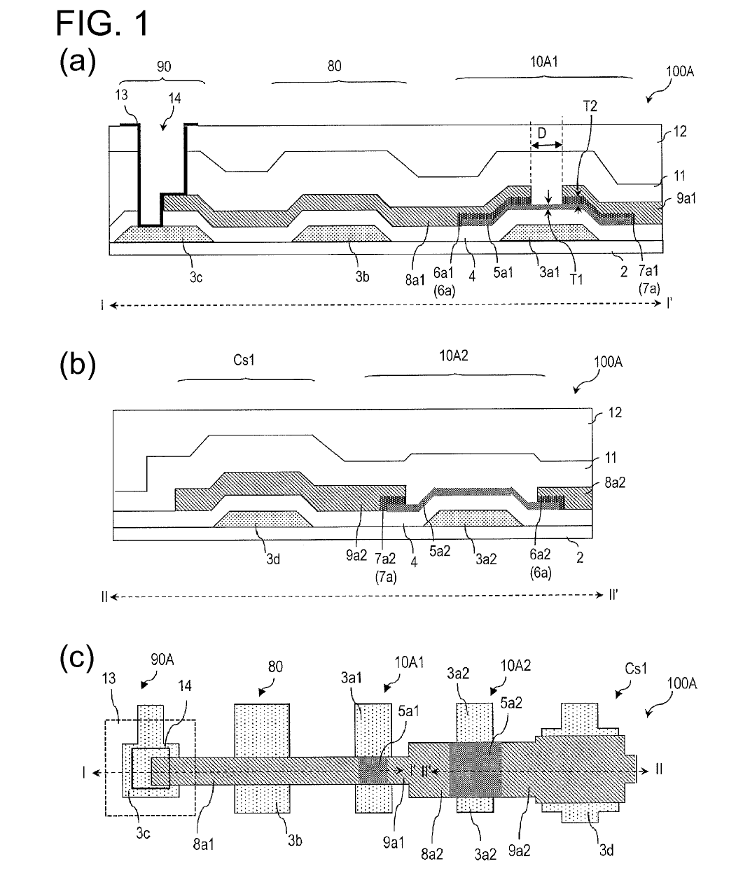

FIGS. 1(a) and 1(b) are schematic cross-sectional views of a semiconductor device 100A of the present embodiment along the line I-I′ and the line II-II′ of FIG. 1(c), and FIG. 1(c) is a schematic plan view of the semiconductor device 100A.

The semiconductor device (TFT substrate) 100A of the present embodiment includes a substrate 2 (a glass substrate, for example), and TFTs 10A1 and 10A2 supported by the substrate 2. The TFTs 10A1 and 10A2 are respectively bottom gate TFTs, for example. The TFTs 10A1 and 10A2 respectively have oxide semiconductor layers 5a1 and 5a1, gate electrodes 3a1 and 3a2, source electrodes 8a1 and 8a2, and drain electrodes 9a1 and 9a2. Also, the TFTs 10A1 and 10A2 respectively have metal oxide layers 6a and 7a formed between at least either of the oxide semiconductor layers 5a1 and 5a2 and the source electrodes 8a1 and 8a2 or the oxide semiconductor layers 5a1 and 5a2 and the drain electrodes 9a1 and 9a2. The metal oxide layers 6a and 7a include a metal (Ti (titanium), for example) included in the source electrodes 8a1 and 8a2 or the drain electrodes 9a1 and 9a2.

T1, T2, and D satisfy D≧1.56×(T2/T1)+0.75 (Formula (1)), where T1 is the thickness of the oxide semiconductor layers 5a1 and 5a2, where T2 is the thickness of the metal oxide layers 6a and 7a, and where D is the distance between the source electrodes 8a1 and 8a2 and the drain electrodes 9a1 and 9a2. Details will be described later, but when T1, T2, and D satisfy such a relation, a highly reliable oxide semiconductor TFT can be attained.

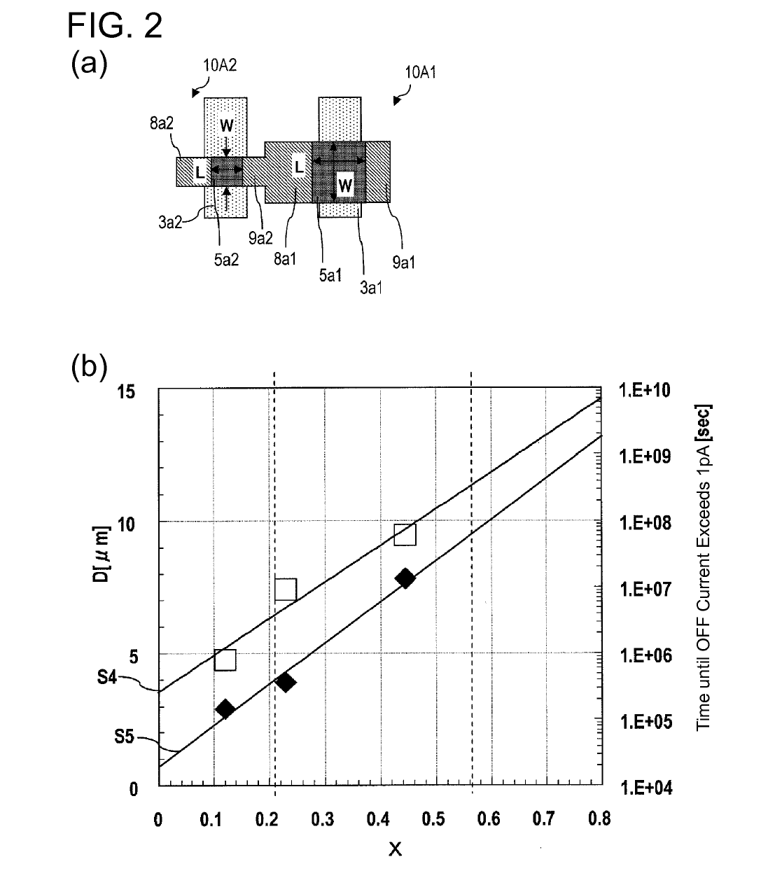

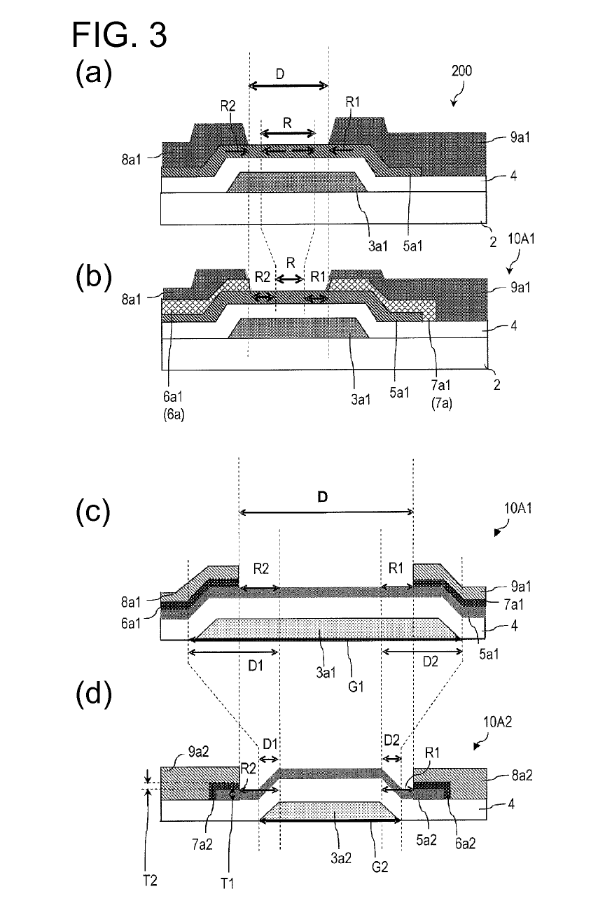

Next, TFT characteristics of the TFTs 10A1 and 10A2 will be described with reference to FIGS. 2 and 3. FIG. 2(a) is a schematic plan view showing respective channel lengths L and channel widths W of the TFTs 10A1 and 10A2. FIG. 2(b) is a graph describing a relation (line S4) between a ratio X and a time until the OFF current (temperature: 60°, illuminance: 5401 x, Vg=−15V, Vs=0V, Vd=10V) of the TFT exceeds 1 pA due to electric stress (temperature: 60°, illuminance: 5401 x, Vg=−15V, Vs=Vd=0V), and a relation (line S5) between the ratio X and a distance D between the source and drain electrodes, according to findings by the inventors of the present invention. FIG. 3(a) is a schematic cross-sectional view of a TFT 200 of a comparison example, and FIGS. 3(b) and 3(c) are schematic cross-sectional views of the TFT 10A1. FIG. 3(d) is a schematic cross-sectional view of the TFT 10A2. In the TFT 200, components in common with the TFT 10A1 are assigned the same reference characters.

The channel length L and the channel width W are set as shown in FIG. 2(a). The channel length L is similar to the distance between the source electrodes 8a1 and 8a2 and the drain electrodes 9a1 and 9a2, and the channel width W is similar to the width of the oxide semiconductor layer 5a1 and 5a2 in a direction perpendicular to the direction of the channel length L. As apparent in FIG. 2(a), the product of the channel length L and the channel width W (L×W) (sometimes referred to as the channel area) is greater in the TFT 10A1 than in the TFT 10A2.

In order to ensure reliability in the semiconductor device having the oxide semiconductor TFTs, it is preferable that the OFF current of the TFTs during a stress test be 1 pA or less. Specifically, after the TFTs 10A1 and 10A2 are driven for 1000 hours (stress test) under a temperature of 60°, with an applied voltage (Vs) to the source electrodes 8a1 and 8a2 and an applied voltage (Vd) to the drain electrodes 9a1 and 9a2 respectively being 0V (Vs=Vd=0), an applied voltage (Vg) to the gate electrodes 3a1 and 3a2 being −30V (Vg=−30V), and an illuminance of 5401 x, it is preferable that the OFF current be at 1 pA or less when voltages are applied such that Vg is −15V (Vg=−15V), Vd is 10V (Vd=10V) and Vs is 0V (Vs=0V) under a temperature of 60° and an illuminance of 5401 x. The inventors of the present invention found that if the ratio X is greater than or equal to 0.21 (X≧0.21), then the OFF current after the stress test is 1 pA or less.

In addition, the inventors of the present invention found the relation between the ratio X between the thickness T1 of the oxide semiconductor layers 5a1 and 5a2 and the thickness T2 of the metal oxide layers 6a and 7a, and the OFF current of the TFTs (refer to FIG. 2(b)). Specifically, as shown in FIG. 2(b), the inventors of the present invention found that the distance D between the source and drain electrodes and the ratio X need to satisfy Formula (1) in order for the OFF current to remain stable at or below 1 pA over a long period of time when Vg is −5V (Vg=−5V) and Vd is 10V (Vd=10V). The upper limit of the distance D is determined as follows.

The mobility (μ) of the oxide semiconductor TFTs is said to be approximately 20 times greater than the mobility of TFTs that have an amorphous silicon (a-Si) layer (a-Si TFT). Thus, even if the oxide semiconductor TFTs are small, approximately the same drive current as a-Si TFTs can be attained. Because the oxide semiconductor TFTs can be made small, if oxide semiconductor TFTs are used in liquid crystal display devices, for example, the aperture ratio of the pixels can be increased. Specifically, if the relation between the mobility (μ), the channel length (L), and the channel width (W) is expressed as μ×W÷L=A (Formula (2)), the channel length L of the channel region in the a-Si TFT is 4 μm (L=4 μm), the channel width W is 25 μm (W=25 μm), and the mobility of the a-Si TFT is μ₁, then the value A of the a-Si TFT is calculated to be 6.25×μ₁ (=6.25μ₁). If the channel width (W) of the oxide semiconductor TFT is set to 3 μm (W=3 μm) and the mobility is 20×μ₁ (=20μ₁), then the A value of the oxide semiconductor TFT is 60×μ₁÷L (=60μ₁/L). Thus, a channel length L that fulfills the condition that the A value of the oxide semiconductor TFT be greater than the A value of the a-Si TFT satisfies 6.25μ₁≦(60μ₁/L). Thus, the channel length L of the oxide semiconductor TFT needs to satisfy L≦9.6. Also, based on Formula (1) above, the ratio X is 0.57 when the channel length L of the oxide semiconductor TFT satisfies L=9.6. As described above, as long as X satisfies 0.21≦X≦0.57, then an oxide semiconductor TFT having a mobility greater than or equal to the mobility of the a-Si TFT with the OFF current remaining at a stable 1 pA or less over a long period of time is attained.

In addition, performing annealing to form the metal oxide layers 6a and 7a presents the following advantages. As shown in FIGS. 3(a) and 3(b), in the region of the oxide semiconductor layer 5a1 of the oxide semiconductor TFT between the source and drain electrodes 8a1 and 9a1, an active channel region R actually functioning as a channel and inactive regions R1 and R2 that do not actually function as a channel are present. The TFT 200 shown in FIG. 200 does not have metal oxide layers 6a and 7a formed by annealing. FIG. 3(b) is the above-mentioned TFT 10A1. As can be seen from FIGS. 3(a) and 3(b), if annealing is performed in order to form the metal oxide layers 6a and 7a, then compared to a case in which annealing is not performed, the active channel region R becomes small and the inactive regions R1 and R2 become large. As a result, it is possible to make the ON current large, and to reduce the power consumption of the semiconductor device. In addition, the TFT 10A1 can be made small, and thus, it is possible to decrease the size of the frame region, which does not contribute to display.

Next, parasitic capacitance in the oxide semiconductor TFT will be described. The parasitic capacitance of the oxide semiconductor TFT of the present embodiment is a total of a capacitance formed in a portion where each of the gate electrodes 3a1 and 3a2 overlap each of the source electrodes 8a1 and 8a2 and each of the drain electrodes 9a1 and 9a2 across each gate insulating film 4, and a capacitance formed in a portion where each of the gate electrodes 3a1 and 3a2 overlap each of the above-mentioned inactive regions R1 and R2 across each gate insulating film 4. In the TFT 10A1 in FIG. 3(c), a length G1 of the gate electrode 3a1 is greater than a distance D between the source and drain electrodes. On the other hand, in the TFT 10A2 in FIG. 3(d), a length G2 of the gate electrode 3a2 is less than the distance D between the source and drain electrodes. As a result, when viewing the portions where the gate electrode 3a1 overlaps the source electrode 8a1 and drain electrode 9a1 and the inactive regions R1 and R2 across the gate insulating film 4 from the direction normal to the TFT 10A1 or TFT 10A2, areas D1 and D2 of the TFT 10A1 are greater than areas D1 and D2 of the TFT 10A2 where the gate electrode 3a2 overlaps the source electrode 8a2 and drain electrode 9a2 and the inactive regions R1 and R2 across the gate insulating film 4. Thus, the parasitic capacitance of the TFT 10A1 is less than the parasitic capacitance of the TFT 10A2. If the parasitic capacitance is small, then the power consumed by the driver circuits to drive the TFTs can be made small. Also, the buffer circuits of the driver circuits to drive the TFTs can be made small, and thus, in a display device having such TFTs, it is possible to reduce the area of the frame region that is located in the periphery of the display region and that does not contribute to display, thus further reducing power consumption.

The TFT 10A1 is a TFT for a driver circuit, for example. The TFT 10A2 is a TFT for pixels, for example. Alternatively, the TFT 10A1 may be used as a TFT for pixels and the TFT 10A2 may be used as a TFT for a driver circuit. The TFTs 10A1 and 10A2 respectively have the gate electrodes 3a1 and 3a2 formed on a substrate 2, the gate insulating films 4 formed on the gate electrodes 3a1 and 3a2, and the oxide semiconductor layers 5a1 and 5a2 formed on the gate insulating film 4. In addition, the metal oxide layers 6a and 7a are formed so as to be in contact with the oxide semiconductor layers 5a1 and 5a2. The source electrodes 8a1 and 8a2 and drain electrodes 9a1 and 9a2 are formed so as to be in contact with the metal oxide layers 6a and 7a. The source electrodes 8a1 and 8a2 and the drain electrodes 9a1 and 9a2 have formed thereon a protective film 11, and on the protective film 11, a photosensitive organic insulating film 12 is formed. Sometimes, the organic insulating film 12 is not formed.

The semiconductor device 100A has gate/source intersections 80, gate/source contact portions 90, and auxiliary capacitance units Cs1, besides the TFTs 10A1 and 10A2.

The gate/source intersection 80 has a first gate portion 3b formed on the substrate 2 of the same conductive film as the one that forms the gate electrode 3a1, the gate insulating film 4 formed on the first gate portion 3b, and the source electrode 8a1. The source electrode 8a1 is formed so as to overlap the gate portion 3b across the gate insulating film 4.

The gate/source contact portion 90 has a second gate portion 3c formed on the substrate 2 of the same conductive film as the one that forms the gate electrode 3a1, the gate insulating film 4 formed on the second gate portion 3c, the source electrode 8a1 formed on the gate insulating film 4, and a transparent electrode 13 (an electrode made of ITO (indium tin oxide), for example). The second gate portion 3c is electrically connected to the source electrode 8a1 by the transparent electrode 13 formed in a contact hole 14.

The auxiliary capacitance unit Cs1 has an auxiliary capacitance electrode 3d formed on the substrate 2 and made of the same conductive film as the one that forms the gate electrode 3a2, the gate insulating film 4 formed on the auxiliary capacitance electrode 3d, and the drain electrode 9a2. The drain electrode 9a2 is formed so as to overlap the auxiliary capacitance electrode 3d across the gate insulating film 4.

The gate electrodes 3a1 and 3a2, the first gate portion 3d, the second gate portion 3c, and the auxiliary capacitance electrode 3d have a layered configuration constituted of Ti/Al (aluminum)/Ti, for example. Besides this, the gate electrodes 3a1 and 3a2, the first gate portion 3b, the second gate portion 3c, and the auxiliary capacitance electrode 3d may have a layered configuration constituted of Mo (molybdenum)/Al/Mo, a single layer structure, a two layer structure, or a structure having four or more layers. Also, the gate electrodes 3a1 and 3a2, the first gate portion 3d, the second gate portion 3c, and the auxiliary capacitance electrode 3d may be made of an element selected from among Al, Cr (chromium), Ta (tantalum), Ti, Mo, and W (tungsten), or of an alloy having these elements. The thickness of the gate electrodes 3a1 and 3a2, the first gate portion 3b, the second gate portion 3c, and the auxiliary capacitance electrode 3d are respectively approximately 50 nm to 900 nm.

The gate insulating film 4 is made of a single layer film made of an SiO₂ (silicon oxide) film and an SiN_{X} (silicon nitride) film. Besides these, the gate insulating film 4 can be made of a single layer film or a multilayer film made of SiO₂ (silicon oxide), SiN_{X} (silicon nitride), SiON (silicon nitride oxide, silicon oxide nitride), Al₂O₃ (aluminum oxide), or tantalum oxide (Ta₂O₅), for example. The thickness of the gate insulating film 4 is set at approximately 50 nm to 600 nm, for example.

The oxide semiconductor layers 5a1 and 5a2 are In—Ga—Zn—O-type semiconductor layers (IGZO layers) in which In (indium), Ga (gallium), and Zn (zinc) are included at a 1:1:1 ratio. The ratio of In, Ga, and Zn can be appropriately chosen. Instead of an IGZO film, a different oxide semiconductor film may be used to form the oxide semiconductor layers 5a1 and 5a2. A Zn—O semiconductor (ZnO) film, an In—Zn—O semiconductor (IZO) film, a Zn—Ti—O semiconductor (ZTO) film, a Cd—Ge—O semiconductor film, a Cd—Pb—O semiconductor film, or the like may be used, for example. It is preferable that an amorphous oxide semiconductor film be used as the oxide semiconductor film. This is because an amorphous oxide semiconductor film can be manufactured at low temperature and can achieve a high mobility. The oxide semiconductor layers 5a1 and 5a2 are respectively approximately 20 nm to 200 nm, for example.

The metal oxide layers 6a1, 6a2, 7a1, and 7a2 have TiO₂ (titanium oxide), for example. Details will be mentioned later, but the metal oxide layers 6a1, 6a2, 7a1, and 7a2 are layers formed when Ti, for example, included in the source electrodes 8a1 and 8a2 and the drain electrodes 9a1 and 9a2 bonds with oxygen included in the oxide semiconductor layers 5a1 and 5a2, thus forming a metal oxide (TiO₂, for example). The metal oxide layers 6a1, 6a2, 7a1, and 7a2 are respectively approximately 4.2 nm to 114 nm in thickness, for example.

The source electrodes 8a1 and 8a2 and the drain electrodes 9a1 and 9a2 have a layered structure of Ti/Al/Ti, for example. Besides this, the source electrodes 8a1 and 8a2 and the drain electrodes 9a1 and 9a2 may have a layered structure of Mo/Al/Mo, or have a single layer structure, a two layer structure, or a structure having four or more layers. The source electrodes 8a1 and 8a2 and the drain electrodes 9a1 and 9a2 may also be formed by an element chosen from among Al, Cr, Ta, Ti, Mo, and W, or an alloy having these elements. The thickness of the gate electrodes 3a1 and 3a2, the first gate portion 3d, the second gate portion 3c, and the auxiliary capacitance electrode 3d are respectively approximately 50 nm to 900 nm.

The protective film 11 is made of a single layer film made of an SiO₂ film. Besides this, the protective film 11 can be made of a single layer film or multilayer film having SiO₂, SiN_{X}, SiON (silicon oxide nitride, silicon nitride oxide), Al₂O₃ (aluminum oxide), or Ta₂O₅ (tantalum oxide), for example. The thickness of the protective film 11 is approximately 50 nm to 900 nm, for example.

The photosensitive organic insulating film 12 is made of a photosensitive acrylic resin, for example. The thickness of the photosensitive organic insulating film 12 is approximately 0.5 μm to 5 μm, for example.

The contact hole 14 is formed in a portion of the gate insulating film 4, the protective film 11, and the photosensitive organic insulating film 12.

The transparent electrode 13 is made of ITO, for example. The thickness of the transparent electrode 13 is approximately 20 nm to 300 nm, for example.

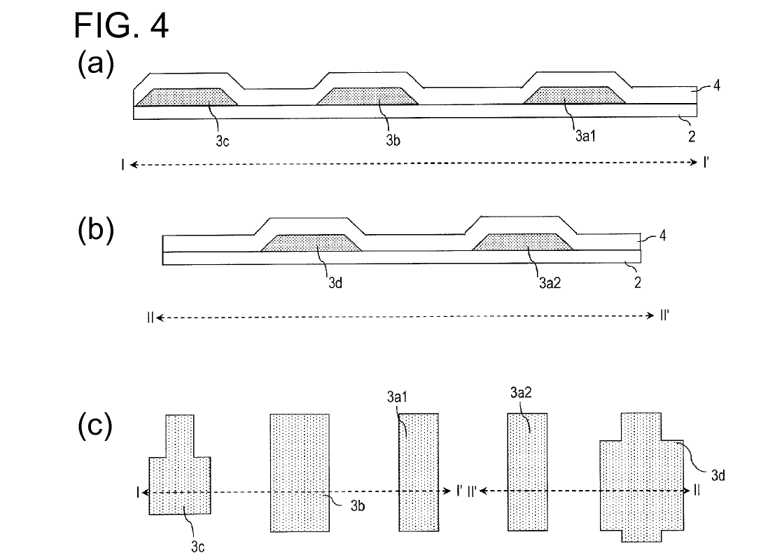

Next, an example of a method of manufacturing the semiconductor device 100A will be described with reference to FIGS. 4 to 7.

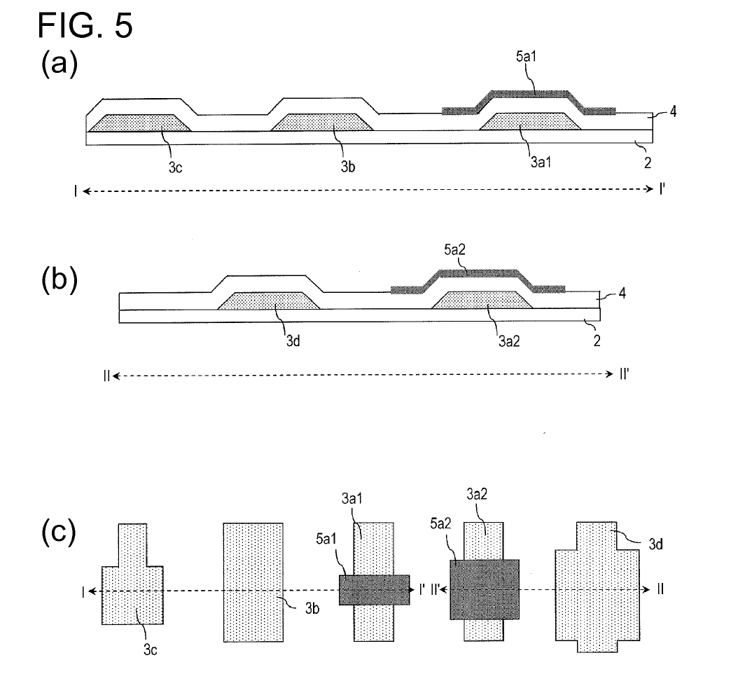

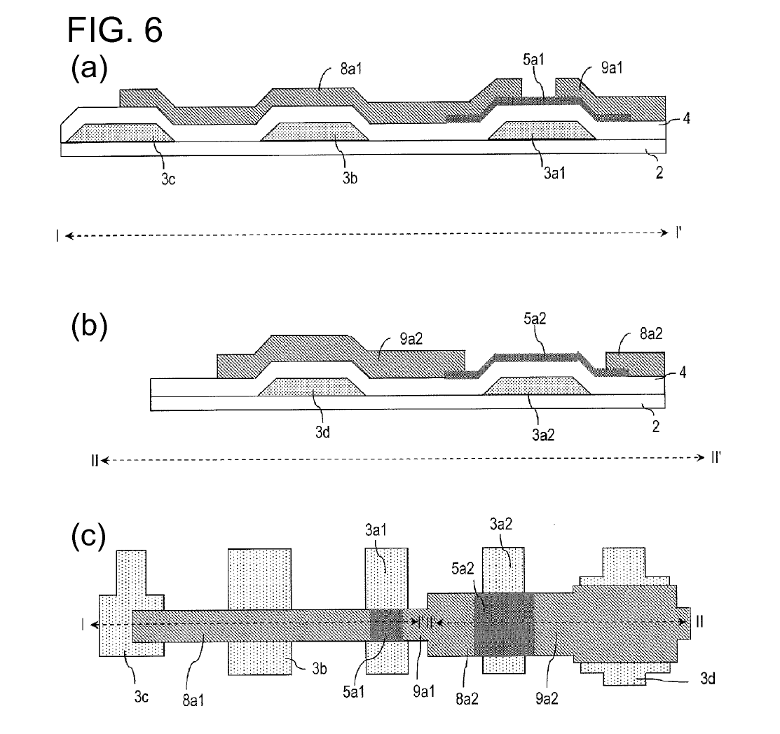

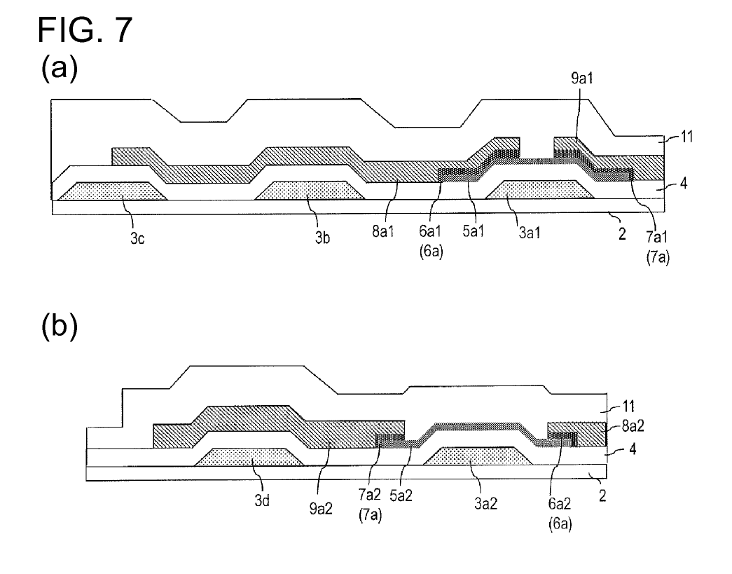

FIGS. 4(a) and 4(b) are cross-sectional views of a step to describe a method of manufacturing a semiconductor device 100A, the cross-sections respectively being along the line I-I′ and the line II-II′ of FIG. 4(c). FIG. 4(c) is a plan view of a step to describe the method of manufacturing the semiconductor device 100A. FIGS. 5(a) and 5(b) are cross-sectional views of a step to describe a method of manufacturing a semiconductor device 100A, the cross-sections respectively being along the line I-I′ and the line II-II′ of FIG. 5(c). FIG. 5(c) is a plan view of a step to describe the method of manufacturing the semiconductor device 100A. FIGS. 6(a) and 6(b) are cross-sectional views of a step to describe a method of manufacturing a semiconductor device 100A, the cross-sections respectively being along the line I-I′ and the line II-II′ of FIG. 6(c). FIG. 6(c) is a plan view of a step to describe the method of manufacturing the semiconductor device 100A. FIGS. 7(a) and 7(b) are cross-sectional views of a step for describing the method of manufacturing the semiconductor device 100A.

First, as shown in FIGS. 4(a) to 4(c), the gate electrodes 3a1 and 3a2, the first gate portion 3b, the second gate portion 3c, and the auxiliary capacitance unit 3d are formed on the substrate 2. The substrate 2 can be made of a transparent insulating substrate such as a glass substrate, for example. The gate electrodes 3a1 and 3a2, the first gate portion 3b, the second gate portion 3c, and the auxiliary capacitance electrode 3d can be formed by forming a first conductive film by sputtering on the substrate 2 and then patterning the first conductive film by photolithography. Here, as the first conductive film, a multilayer film having three layers is formed by forming a Ti film (thickness of approximately 10 nm to 100 nm), an Al film (thickness of approximately 50 nm to 500 nm), and a Ti film (thickness of approximately 50 nm to 300 nm) in this order from the substrate 2 side. The first conductive film may alternatively be made of a single layer film having Ti, Mo, Ta, W, Cu, Al, Cr, or the like, or a multilayer film or alloy film including these, for example.

Next, the gate insulating film 4 is formed so as to cover the gate electrodes 3a1 and 3a2, the first gate portion 3b, the second gate portion 3c, and the auxiliary capacitance electrode 3d. The gate insulating film 4 can be formed by CVD. As the insulating film in the present embodiment, a multilayer film having two layers is formed by forming an SiN_{X} film (thickness of approximately 100 nm to 500 nm) and an SiO₂ film (thickness of approximately 20 nm to 100 nm) in this order from the substrate 2 side. This configuration in which the upper surface of the gate insulating film 4 is an SiO₂ film is preferable due to the fact that even if there is oxygen loss in the oxide semiconductor layers 5a1 and 5a2 thereabove, the oxygen can be supplemented from the SiO₂. Besides this, the gate insulating film 4 can be made of a single layer film or a multilayer film made of SiO₂, SiN_{X}, SiON, Al₂O₃, or Ta₂O₅, for example.

Next, as shown in FIGS. 5(a) to 5(c), the oxide semiconductor layers 5a1 and 5a2 are formed on the gate insulating film 4. Specifically, an IGZO film of approximately 20 nm to 200 nm in thickness, for example, is formed on the gate insulating film 4 by sputtering. Then, by photolithography, the IGZO film is patterned, thus forming the oxide semiconductor layers 5a1 and 5a2. The oxide semiconductor layers 5a1 and 5a2 are formed so as to respectively overlap the corresponding gate electrodes 3a1 and 3a2 across the gate insulating film 4. Here, as the oxide semiconductor layers 5a1 and 5a2, an In—Ga—Zn—O-type semiconductor layer (IGZO layer) including In, Ga, and Zn at a 1:1:1 ratio is formed, but the ratio of In, Ga, and Zn can be appropriately chosen.

Next, as shown in FIGS. 6(a) to 6(c), on the oxide semiconductor layers 5a1 and 5a2, a lower layer Ti film (thickness of approximately 5 nm to 200 nm) is formed, an Al film (thickness of approximately 50 nm to 900 nm) is formed thereon, and an upper layer Ti film (thickness of approximately 10 nm to 500 nm) is formed thereon, these films being formed by sputtering. These layered conductive films are patterned by photolithography, thus forming the source electrodes 8a1 and 8a2 and the drain electrodes 9a1 and 9a2. Of the source electrodes 8a1 and 8a2 and the drain electrodes 9a1 and 9a2, the lower layer Ti films are in contact with the oxide semiconductor layers 5a1 and 5a2. Of the metals included in the source electrodes 8a1 and 8a2 and the drain electrodes 9a1 and 9a2, it is preferable that the metal in contact with the oxide semiconductor layer 5a1 and 5a2 be Ti. Ti bonds with oxygen included in the oxide semiconductor layers 5a1 and 5a2 with ease, and thus, it is possible to form the metal oxide layers 6a and 7a to be described later with ease.

Next, as shown in FIGS. 7(a) and 7(b), the protective film 11 (passivation film) is formed on the source electrodes 8a1 and 8a2 and the drain electrodes 9a1 and 9a2. Here, an SiO₂ film is formed by CVD as the protective film 11. Besides this, it is possible to form, as the protective film 11, an SiO₂ film, an SiN_{X} film, an SiON film, or a multilayer film including these by CVD. It is preferable that the protective film 11 be approximately 5 nm to 900 nm in thickness.

Next, annealing is performed for 0.5 hours to 8 hours at a temperature of 100° C. to 500° C. in air. As a result, as shown in FIGS. 7(a) and 7(b), metal oxide layers 6a1 and 6a2 are formed between the source electrodes 8a1 and 8a2 and the oxide semiconductor layers 5a1 and 5a2, and the metal oxide layers 7a1 and 7a2 are formed between the drain electrodes 9a1 and 9a2 and the oxide semiconductor layers 5a1 and 5a2. The metal oxide layers 6a and 7a are layers formed when a metal (Ti, for example) included in the source electrodes 8a1 and 8a2 and the drain electrodes 9a1 and 9a2 bonds with oxygen included in the oxide semiconductor layers 5a1 and 5a2. Thus, the metal oxide layers 6a and 7a include TiO₂, for example. Also, the portions of the oxide semiconductor layers 5a1 and 5a2 that lose oxygen become n-type portions. The n-type portions are the above-mentioned inactive regions.

Next, as shown in FIGS. 1(a) to 1(c), the photosensitive organic insulating film 12 is formed by photolithography on the protective film 11. Then, the contact hole 14 is formed by a known method, and after exposing a portion of the source electrode 8a1 and a portion of the second gate portion 3c, the transparent electrode 13 is formed by sputtering and/or photolithography. The transparent electrode 13 is formed so as to be electrically connected to the second gate portion 3c and the source electrode 8a1 in the contact hole 14. The thickness of the transparent electrode 13 is approximately 20 nm to 300 nm, for example.

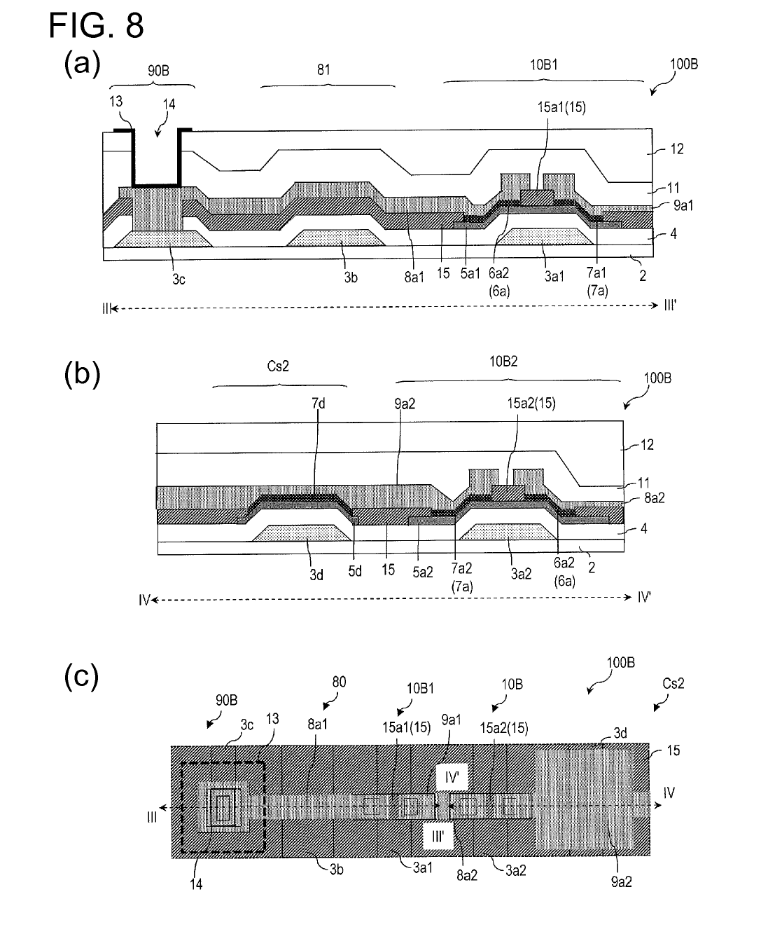

Next, a semiconductor device 100B of another embodiment according to the present invention will be explained with reference to FIG. 8. FIGS. 8(a) and 8(b) are schematic cross-sectional views of the semiconductor device 100B along the line III-III′ and the line IV-IV′ in FIG. 8(c), and FIG. 8(c) is a schematic plan view of the semiconductor device 100B. Constituting elements that are shared with the semiconductor device 100A will be assigned the same reference characters, and duplicate explanations will be avoided.

The semiconductor device 100B differs from the semiconductor device 100A in that the semiconductor device 100B has an interlayer insulating layer 15. The semiconductor device 100B (TFT substrate) includes a substrate 2 (glass substrate, for example), and TFTs 10B1 and 10B2 supported by the substrate 2. The TFTs 10B1 and 10B2 are respectively bottom gate TFTs, for example. The TFTs 10B1 and 10B2 respectively have oxide semiconductor layers 5a1 and 5a1, gate electrodes 3a1 and 3a2, source electrodes 8a1 and 8a2, drain electrodes 9a1 and 9a2, and etching stopper layers 15a1 and 15a2. The etching stopper layers 15a1 and 15a2 are formed on the oxide semiconductor layers 5a1 and 5a2, and are formed so as to cover the channel regions of the oxide semiconductor layers 5a1 and 5a2. Also, the TFTs 10B1 and 10B2 respectively have metal oxide layers 6a and 7a formed between at least either of the oxide semiconductor layers 5a1 and 5a2 or the source electrodes 8a1 and 8a2 and the oxide semiconductor layers 5a1 and 5a2 and the drain electrodes 9a1 and 9a2. The metal oxide layers 6a and 7a include a metal (Ti (titanium), for example) included in the source electrodes 8a1 and 8a2 or the drain electrodes 9a1 and 9a2.

T1, T2, and D satisfy D≧1.56×(T2/T1)+0.75 where T1 is the thickness of the oxide semiconductor layers 5a1 and 5a2, T2 is the thickness of the metal oxide layers 6a and 7a, and D is the distance between the source electrodes 8a1 and 8a2 and the drain electrodes 9a1 and 9a2. As stated above, if T1, T2, and D satisfy such a relation, then a highly reliable oxide semiconductor TFT can be attained. Also, as described above, as long as X (X=T2/T1) satisfies 0.21≦X≦0.57, then an oxide semiconductor TFT having a mobility greater than or equal to the mobility of the a-Si TFT with the OFF current remaining at a stable 1 pA or less over a long period of time is attained.

The TFT 10B1 is a TFT for a driver circuit, for example. The TFT 10B2 is a TFT for pixels, for example. The TFTs 10B1 and 10B2 respectively have the gate electrodes 3a1 and 3a2 formed on a substrate 2, the gate insulating films 4 formed on the gate electrodes 3a1 and 3a2, and the oxide semiconductor layers 5a1 and 5a2 and interlayer insulating layer 15 formed on the gate insulating film 4. The oxide semiconductor layers 5a1 and 5a2 are formed so as to respectively overlap the gate electrodes 3a1 and 3a2 across the gate insulating film 4. Portions of the interlayer insulating layer 15 are formed so as to cover the channel regions of the oxide semiconductor layers 5a1 and 5a2, and these portions function as the etching stopper layers 15a1 and 15a2. In addition, the metal oxide layers 6a and 7a are formed so as to be in contact with the oxide semiconductor layers 5a1 and 5a2. The source electrodes 8a1 and 8a2 and drain electrodes 9a1 and 9a2 are formed so as to be in contact with the metal oxide layers 6a and 7a. Also, portions of the source electrodes 8a1 and 8a2 and the drain electrodes 9a1 and 9a2 are formed on the etching stopper layers 15a1 and 15a2. The source electrodes 8a1 and 8a2 and the drain electrodes 9a1 and 9a2 have formed thereon a protective film 11, and on the protective film 11, a photosensitive organic insulating film 12 is formed. Sometimes, the organic insulating film 12 is not formed.

Like the semiconductor device 100A, the semiconductor device 100B has gate/source intersections 81, gate/source contact portions 90B, and auxiliary capacitance units Cs2, besides the TFTs 10B1 and 10B2.

The gate/source intersection 81 has a first gate portion 3b formed on the substrate 2 of the same conductive film as the one that forms the gate electrode 3a1, the gate insulating film 4 formed on the first gate portion 3b, the interlayer insulating layer 15 formed on the gate insulating film 4 and the source electrode 8a1 formed on the interlayer insulating layer 15. The source electrode 8a1 is formed so as to overlap the gate portion 3b across the gate insulating film 4 and the interlayer insulating layer 15. The gate/source intersection 81 differs from the gate/source intersection 80 in that there are two insulating layers between the first gate portion 3b and the source electrode 8a1. Thus, it is possible to reduce the parasitic capacitance of the gate/source intersection 81 to less than that of the gate/source intersection 80.

The gate/source contact portion 90B has a second gate portion 3c formed on the substrate 2 of the same conductive film as the one that forms the gate electrode 3a1, a gate insulating film 4 formed on the second gate portion 3c, an interlayer insulating layer 15 formed on the gate insulating film 4, a source electrode 8a1 formed on the interlayer insulating layer 15, and a transparent electrode 13. The second gate portion 3c is electrically connected to the source electrode 8a1, and the source electrode 8a1 is electrically connected to the transparent electrode 13 formed in the contact hole 14. In the gate/source contact portion 90B having such a structure, the transparent electrode 13 does not need to be formed up to the second gate portion 3c as in the gate/source contact portion 90, and thus, the transparent electrode 13 is not susceptible to disconnection.

The auxiliary capacitance unit Cs2 has an auxiliary capacitance electrode 3d formed on the substrate 2 and made of the same conductive film as the one that forms the gate electrode 3a2, the gate insulating film 4 formed on the auxiliary capacitance electrode 3d, the oxide semiconductor layer 5d formed on the gate insulating film 4, the metal oxide layer 7d formed on the oxide semiconductor layer 5d, and the drain electrode 9a2 formed on the metal oxide layer 7d. The drain electrode 9a2 is formed so as to overlap the auxiliary capacitance electrode 3d across the gate insulating film 4, the oxide semiconductor layer 5, and the metal oxide layer 7d.

The interlayer insulating layer 15 is made of a single layer film made of an SiO₂ film. Besides this, the interlayer insulating film 15 can be made of a single layer film or multilayer film having SiO₂, SiN_{X}, SiON (silicon oxide nitride, silicon nitride oxide), Al₂O₃ (aluminum oxide), or Ta₂O₅ (tantalum oxide), for example. The thickness of the interlayer insulating layer 13 is approximately 10 nm to 900 nm, for example.

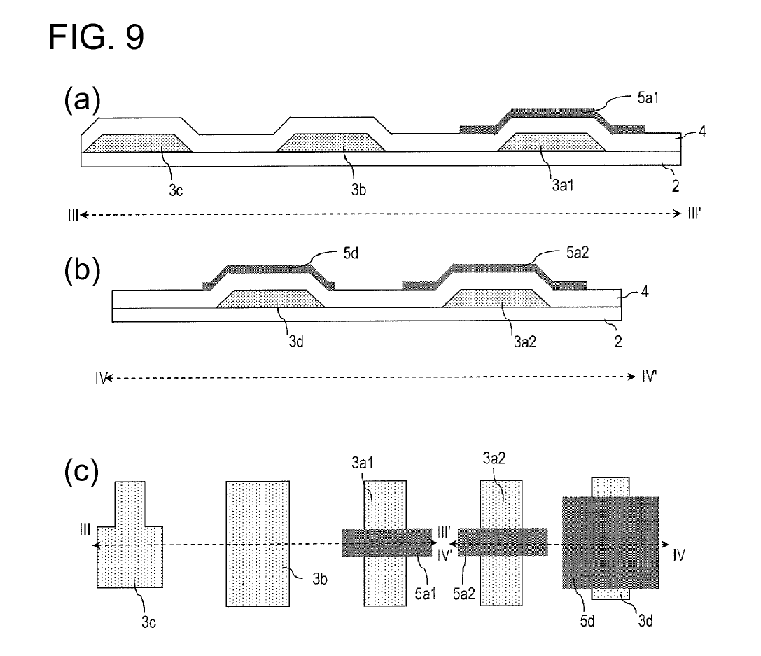

Next, an example of a method of manufacturing the semiconductor device 100B will be described with reference to FIGS. 9 to 12.

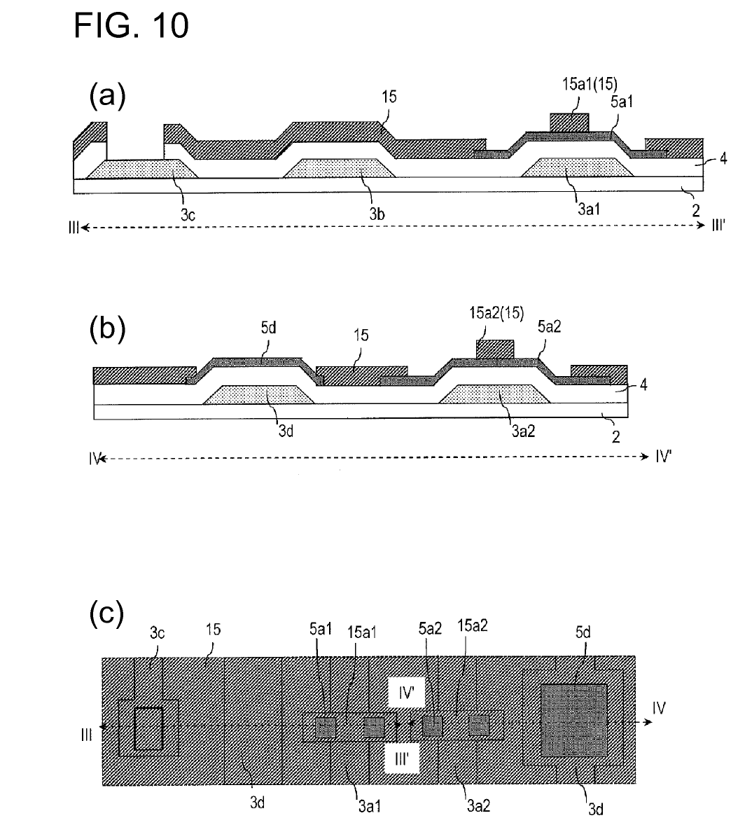

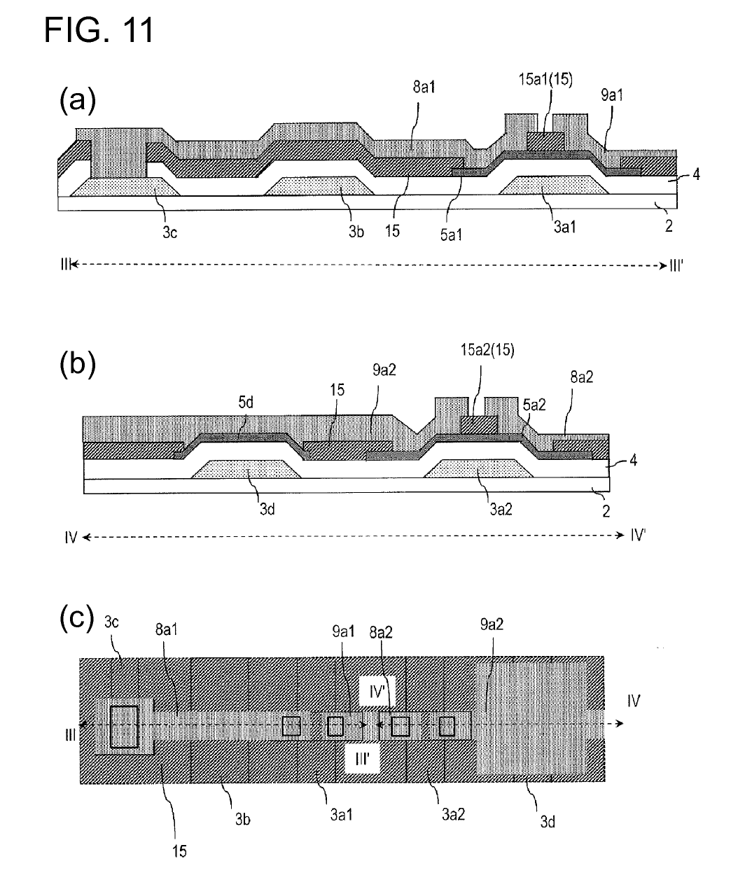

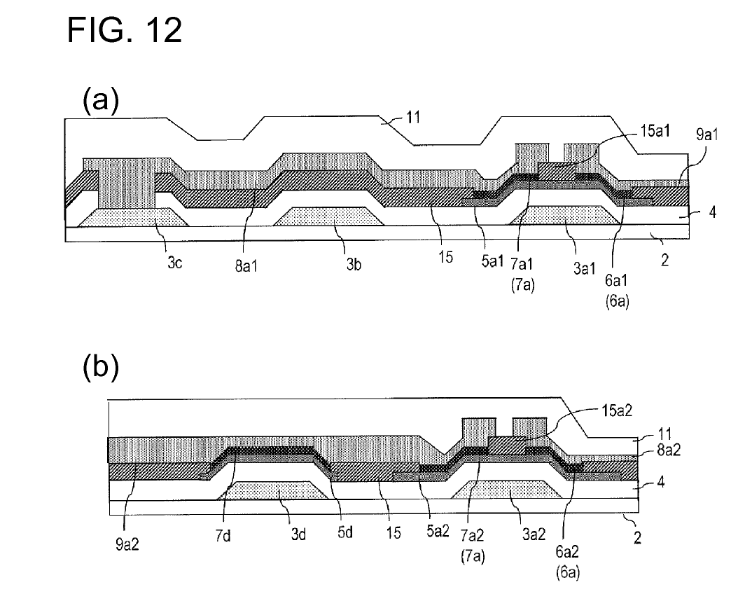

FIGS. 9(a) and 9(b) are cross-sectional views of a step to describe a method of manufacturing a semiconductor device 100B, the cross-sections respectively being along the line III-III′ and the line IV-IV′ of FIG. 9(c). FIG. 9(c) is a plan view of a step to describe the method of manufacturing the semiconductor device 100B. FIGS. 10(a) and 10(b) are cross-sectional views of a step to describe a method of manufacturing a semiconductor device 100B, the cross-sections respectively being along the line III-III′ and the line IV-IV′ of FIG. 10(c). FIG. 10(c) is a plan view of a step to describe the method of manufacturing the semiconductor device 100B. FIGS. 11(a) and 11(b) are cross-sectional views of a step to describe a method of manufacturing the semiconductor device 100B, the cross-sections respectively being along the line III-III′ and the line IV-IV′ of FIG. 11(c). FIG. 11(c) is a plan view of a step to describe the method of manufacturing the semiconductor device 100B. FIGS. 12(a) and 12(b) are cross-sectional views of a step for describing the method of manufacturing the semiconductor device 100B.

As described above, the gate electrodes 3a1 and 3a2, the first gate portion 3b, the second gate portion 3c, the auxiliary capacitance electrode 3d, and the gate insulating film 4 are formed on the substrate 2.

Next, as shown in FIGS. 9(a) to 9(c), the oxide semiconductor layers 5a1, 5a2, and 5d are formed on the gate insulating film 4. Specifically, an IGZO film of approximately 20 nm to 200 nm in thickness, for example, is formed on the gate insulating film 4 by sputtering. Then, by photolithography, the IGZO film is patterned, thus forming the oxide semiconductor layers 5a1, 5a2, and 5d. The oxide semiconductor layers 5a1 and 5a2 are formed so as to respectively overlap the corresponding gate electrodes 3a1 and 3a2 across the gate insulating film 4. The oxide semiconductor layer 5d is formed so as to overlap the auxiliary capacitance electrode 3d across the gate insulating film 4.

Next, as shown in FIGS. 10(a) to 10(c), the interlayer insulating layer 15 is formed on the gate insulating film 4. Portions of the interlayer insulating layer 15 are formed on the oxide semiconductor layers 5a1 and 5a2, and function as etching stopper layers 15a1 and 15a2. The interlayer insulating layer 15 is formed of an SiO₂ film by CVD. Besides this, the interlayer insulating layer 15 can be formed of an SiO₂ film, an SiN_{X} film, an SiON film, or a multilayer film including these by CVD. It is preferable that the interlayer insulating layer 15 be approximately 10 nm to 900 nm in thickness.

Next, annealing is performed in air for 0.5 hours to 8 hours at a temperature of approximately 100° to 500°. By annealing in this manner, it is possible to repair lattice defects that occur in the oxide semiconductor layer 5a1, 5a2, and 5d when forming the interlayer insulating layer 15.

Next, as shown in FIGS. 11(a) to 11(c), a lower layer Ti film (thickness of approximately 5 nm to 200 nm) is formed, an Al film (thickness of approximately 50 nm to 900 nm) is formed thereon, and an upper layer Ti film (thickness of approximately 10 nm to 500 nm) is formed thereon, all of these films being formed on the oxide semiconductor layers 5a1, 5a2, and 5d by sputtering. These layered conductive films are patterned by photolithography, thus forming the source electrodes 8a1 and 8a2 and the drain electrodes 9a1 and 9a2. Portions of the source electrodes 8a1 and 8a2 and the drain electrodes 9a1 and 9a2 are formed on the etching stopper layers 15a1 and 15a2. Of the source electrodes 8a1 and 8a2 and the drain electrodes 9a1 and 9a2, the lower layer Ti films are in contact with the oxide semiconductor layers 5a1 and 5a2. The lower layer Ti film of the drain electrode 9a2 is in contact with the oxide semiconductor layer 5d. Of the metals included in the source electrodes 8a1 and 8a2 and the drain electrodes 9a1 and 9a2, it is preferable that the metal in contact with the oxide semiconductor layers 5a1, 5a2, and 5d be Ti. Ti bonds with oxygen included in the oxide semiconductor layers 5a1, 5a2, and 5d with ease, and thus, it is possible to form the metal oxide layers 6a, 7a, and 7d to be described later with ease.

In addition, the source electrode 8a1 is in contact with the second gate portion 3c in an opening formed in the gate insulating film 4 and the interlayer insulating layer 15, and is electrically connected to the second gate portion 3c.

Next, as shown in FIGS. 12(a) and 12(b), the protective film 11 (passivation film) is formed on the source electrodes 8a1 and 8a2 and the drain electrodes 9a1 and 9a2 by the above-mentioned method.

Next, annealing is performed for 0.5 hours to 8 hours at a temperature of 100° C. to 500° C. in air. As a result, as shown in FIGS. 12(a) and 12(b), metal oxide layers 6a1 and 6a2 are formed between the source electrodes 8a1 and 8a2 and the oxide semiconductor layers 5a1 and 5a2, and the metal oxide layers 7a1 and 7a2 are formed between the drain electrodes 9a1 and 9a2 and the oxide semiconductor layers 5a1 and 5a2. In addition, the metal oxide layer 7d is formed between the drain electrode 9a2 and the oxide semiconductor layer 5d. The metal oxide layers 6a, 7a, and 7d are layers formed when a metal (Ti, for example) included in the source electrodes 8a1 and 8a2 and the drain electrodes 9a1 and 9a2 bonds with oxygen included in the oxide semiconductor layers 5a1, 5a2, and 5d. Thus, the metal oxide layers 6a, 7a, and 7d include TiO₂, for example. Also, the portions of the oxide semiconductor layers 5a1 and 5a2 that lose oxygen become n-type portions. The n-type portions are the above-mentioned inactive regions. Similarly, portions of the oxide semiconductor layer 5d that lose oxygen become n-type portions.

Next, as shown in FIGS. 8(a) to 8(c), the photosensitive organic insulating film 12 is formed by photolithography on the protective film 11. Then, the contact hole 14 is formed by a known method, and after exposing a portion of the source electrode 8a1 and a portion of the second gate portion 3c, the transparent electrode 13 is formed by sputtering and/or photolithography. The transparent electrode 13 is formed so as to be electrically connected to the source electrode 8a1 in the contact hole 14. The thickness of the transparent electrode 13 is approximately 20 nm to 300 nm, for example.

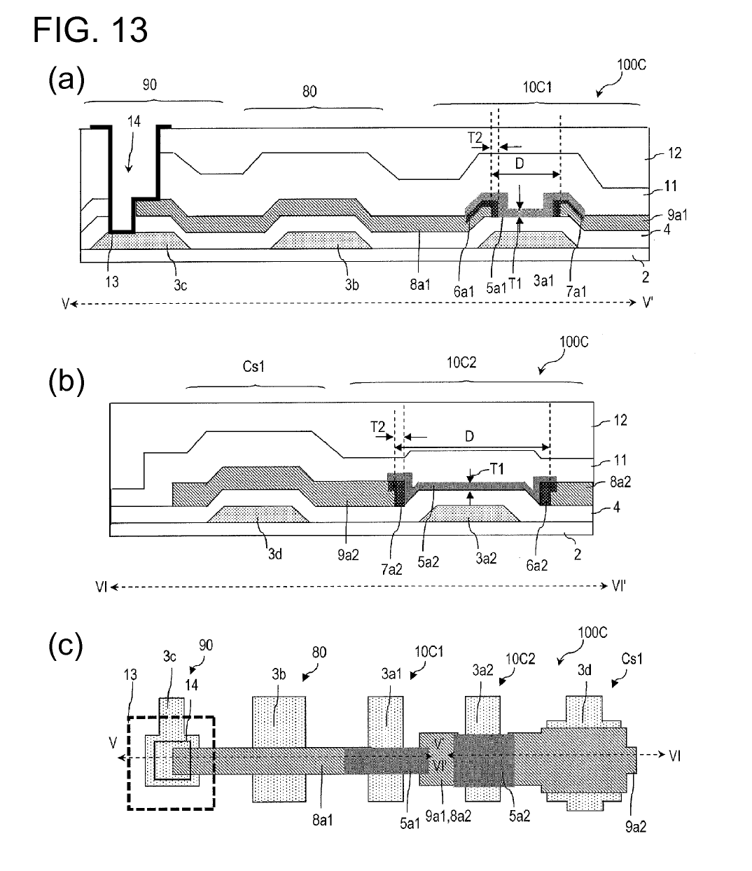

Next, a semiconductor device 100C of another embodiment according to the present invention will be explained with reference to FIG. 13. FIGS. 13(a) and 13(b) are schematic cross-sectional views of the semiconductor device 100C respectively along the line V-V′ and the line VI-VI′ of FIG. 13(c). FIG. 13(c) is a schematic plan view of the semiconductor device 100B. Constituting elements that are shared with the semiconductor device 100A will be assigned the same reference characters, and duplicate explanations will be avoided.

The semiconductor device 100C differs from the semiconductor device 100A in that the oxide semiconductor layers 5a1 and 5a2 are formed below the source electrodes 8a1 and 8a2 and the drain electrodes 9a1 and 9a2. The semiconductor device 100C (TFT substrate) includes a substrate 2 (glass substrate, for example), and TFTs 10C1 and 10C2 supported by the substrate 2. The TFTs 10C1 and 10C2 are respectively bottom gate TFTs, for example. The TFTs 10C1 and 10C2 respectively have oxide semiconductor layers 5a1 and 5a1, gate electrodes 3a1 and 3a2, source electrodes 8a1 and 8a2, and drain electrodes 9a1 and 9a2. Also, the TFTs 10C1 and 10C2 respectively have metal oxide layers 6a and 7a formed between at least either of the oxide semiconductor layers 5a1 and 5a2 and the source electrodes 8a1 and 8a2 or the oxide semiconductor layers 5a1 and 5a2 and the drain electrodes 9a1 and 9a2. The metal oxide layers 6a and 7a include a metal (Ti (titanium), for example) included in the source electrodes 8a1 and 8a2 or the drain electrodes 9a1 and 9a2.

T1, T2, and D satisfy D≧1.56×(T2/T1)+0.75 where T1 is the thickness of the oxide semiconductor layers 5a1 and 5a2, T2 is the thickness of the metal oxide layers 6a and 7a, and D is the distance between the source electrodes 8a1 and 8a2 and the drain electrodes 9a1 and 9a2. If T1, T2, and D satisfy such a relation, then as stated above, a highly reliable oxide semiconductor TFT can be attained. Also, as described above, as long as X (X=T2/T1) satisfies 0.21≦X≦0.57, then an oxide semiconductor TFT having a mobility greater than or equal to the mobility of the a-Si TFT with the OFF current remaining at a stable 1 pA or less over a long period of time is attained.

The TFT 10C1 is a TFT for a driver circuit, for example. The TFT 10C2 is a TFT for pixels, for example. The TFTs 10C1 and 10C2 have gate electrodes 3a1 and 3a2 respectively formed on the substrate 2, a gate insulating film 4 formed on the gate electrodes 3a1 and 3a2, source electrodes 8a1 and 8a2 and drain electrodes 9a1 and 9a2 formed on the gate insulating film 4, and oxide semiconductor layers 5a1 and 5a2 formed on the source electrodes 8a1 and 8a2 and the drain electrodes 9a1 and 9a2. The oxide semiconductor layers 5a1 and 5a2 are formed so as to respectively overlap the gate electrodes 3a1 and 3a2 across the gate insulating film 4. In addition, the metal oxide layers 6a and 7a are formed so as to be in contact with the oxide semiconductor layers 5a1 and 5a2. The source electrodes 8a1 and 8a2 and drain electrodes 9a1 and 9a2 are formed so as to be in contact with the metal oxide layers 6a and 7a. The source electrodes 8a1 and 8a2 and the drain electrodes 9a1 and 9a2 have formed thereon a protective film 11, and on the protective film 11, a photosensitive organic insulating film 12 is formed. Sometimes, the organic insulating film 12 is not formed.

Like the semiconductor device 100A, the semiconductor device 100C has gate/source intersections 80, gate/source contact portions 90, and auxiliary capacitance units Cs1, besides the TFTs 10C1 and 10C2.

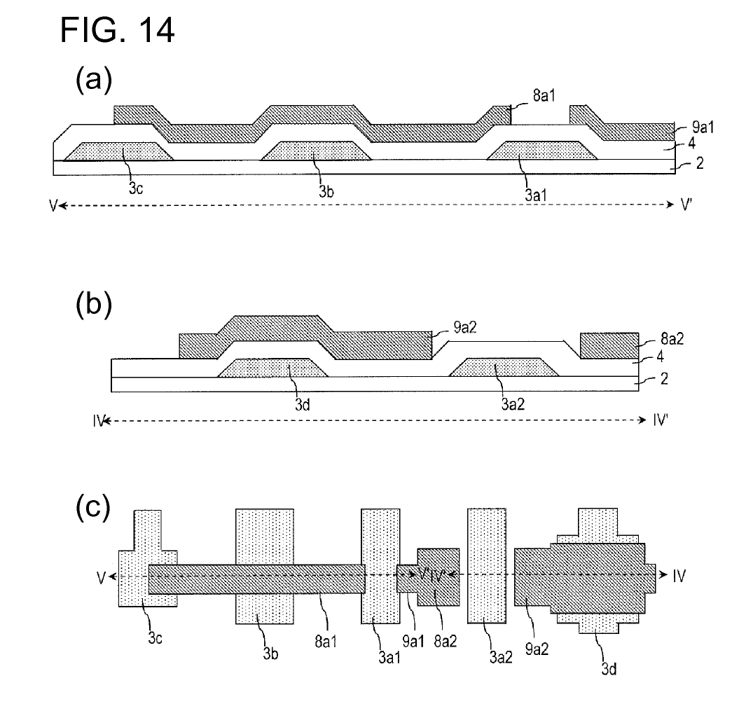

Next, an example of a method of manufacturing the semiconductor device 100C will be described with reference to FIGS. 14 to 16.

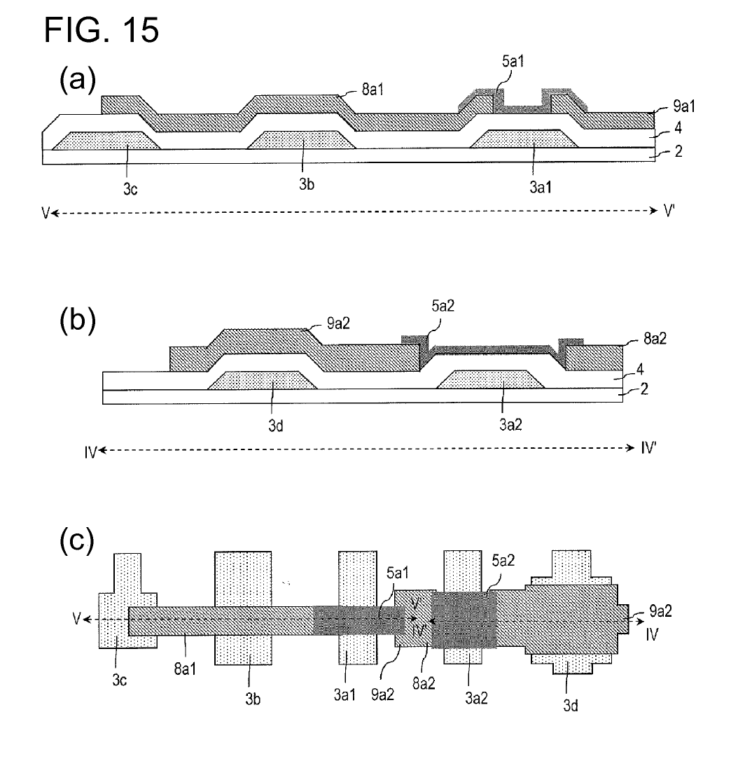

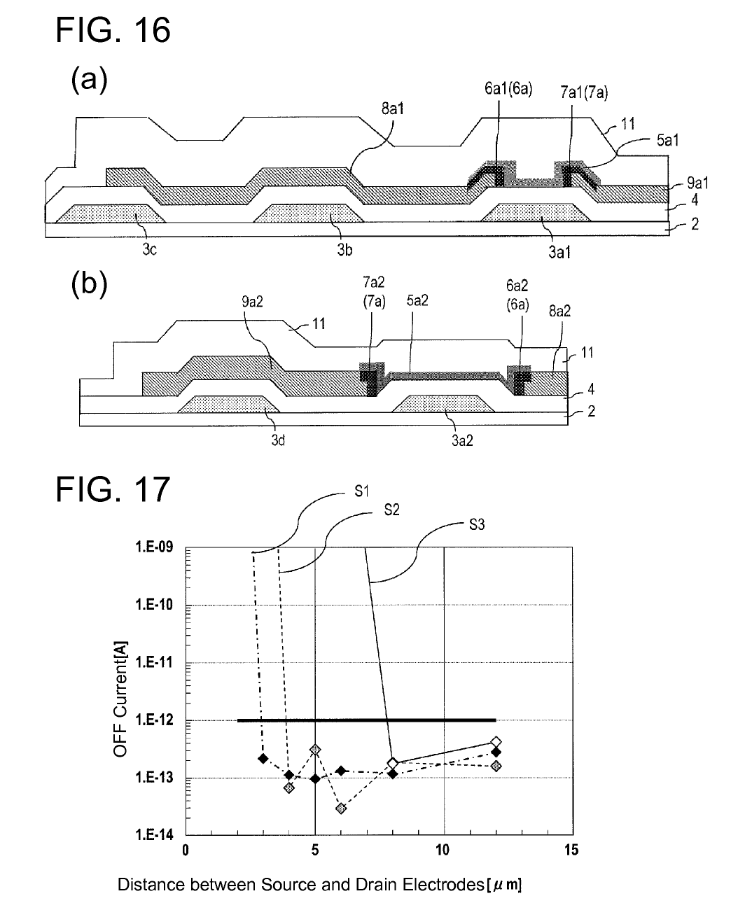

FIGS. 14(a) and 14(b) are cross-sectional views of a step to described a method of manufacturing the semiconductor device 100C respectively along the line V-V′ and the line VI-VI′ of FIG. 14(c). FIG. 14(c) is a plan view of a step to describe the method of manufacturing the semiconductor device 100C. FIGS. 15(a) and 15(b) are cross-sectional views of a step to described a method of manufacturing the semiconductor device 100C respectively along the line V-V′ and the line VI-VI′ of FIG. 15(c). FIG. 15(c) is a plan view of a step to describe the method of manufacturing the semiconductor device 100C. FIGS. 16(a) and 16(b) are cross-sectional views of a step for describing the method of manufacturing the semiconductor device 100C.

As described above, the gate electrodes 3a1 and 3a2, the first gate portion 3b, the second gate portion 3c, the auxiliary capacitance electrode 3d, and the gate insulating film 4 are formed on the substrate 2.

Next, as shown in FIGS. 14(a) to 14(c), a lower Ti film (thickness of approximately 5 nm to 200 nm) is formed, an Al film (thickness of approximately 50 nm to 900 nm) is formed thereon, and an upper layer Ti film (thickness of approximately 10 nm to 500 nm) is formed thereon, all of these films being formed on the gate insulating film 4 by sputtering. These layered conductive films are patterned by photolithography, thus forming the source electrodes 8a1 and 8a2 and the drain electrodes 9a1 and 9a2.

Next, as shown in FIGS. 15(a) to 15(c), the oxide semiconductor layers 5a1 and 5a2 are formed on the source electrodes 8a1 and 8a2 and the drain electrodes 9a1 and 9a2. Specifically, an IGZO film of approximately 20 nm to 200 nm in thickness, for example, is formed on the gate insulating film 4 by sputtering. Then, by photolithography, the IGZO film is patterned, thus forming the oxide semiconductor layers 5a1 and 5a2. The oxide semiconductor layers 5a1 and 5a2 are formed so as to respectively overlap the corresponding gate electrodes 3a1 and 3a2 across the gate insulating film 4.

Of the source electrodes 8a1 and 8a2 and the drain electrodes 9a1 and 9a2, the upper layer Ti films are in contact with the oxide semiconductor layers 5a1 and 5a2. Of the metals included in the source electrodes 8a1 and 8a2 and the drain electrodes 9a1 and 9a2, it is preferable that the metal in contact with the oxide semiconductor layer 5a1 and 5a2 be Ti. Ti bonds with oxygen included in the oxide semiconductor layers 5a1 and 5a2 with ease, and thus, it is possible to form the metal oxide layers 6a and 7a to be described later with ease.

Next, the protective film 11 (passivation film) is formed on the source electrodes 8a1 and 8a2 and the drain electrodes 9a1 and 9a2 by the above-mentioned method.

Next, annealing is performed for 0.5 hours to 8 hours at a temperature of 100° C. to 500° C. in air. As a result, as shown in FIGS. 16(a) and 16(b), metal oxide layers 6a1 and 6a2 are formed between the source electrodes 8a1 and 8a2 and the oxide semiconductor layers 5a1 and 5a2, and the metal oxide layers 7a1 and 7a2 are formed between the drain electrodes 9a1 and 9a2 and the oxide semiconductor layers 5a1 and 5a2. The metal oxide layers 6a and 7a are layers formed when a metal (Ti, for example) included in the source electrodes 8a1 and 8a2 and the drain electrodes 9a1 and 9a2 bonds with oxygen included in the oxide semiconductor layers 5a1 and 5a2. Thus, the metal oxide layers 6a and 7a include the metal oxide (TiO₂, for example). Also, the portions of the oxide semiconductor layers 5a1 and 5a2 that lose oxygen become n-type portions. The n-type portions are the above-mentioned inactive regions.

Next, as shown in FIGS. 13(a) to 13(c), the photosensitive organic insulating film 12 is formed by photolithography on the protective film 11. Then, the contact hole 14 is formed by a known method, and after exposing a portion of the source electrode 8a1 and a portion of the second gate portion 3c, the transparent electrode 13 is formed by sputtering and/or photolithography. The transparent electrode 13 is formed so as to be electrically connected to the source electrode 8a1 and the second gate portion 3c in the contact hole 14. The thickness of the transparent electrode 13 is approximately 20 nm to 300 nm, for example.

As described above, by the liquid crystal display devices 100A to 100C, a semiconductor device with good TFT characteristics is provided without increasing the size of the TFTs.

### INDUSTRIAL APPLICABILITY

The embodiments of the present invention can be widely applied to devices including thin film transistors such as circuit substrates such as active matrix substrates, display devices such as liquid crystal display devices, organic electroluminescent (EL) display devices, and inorganic electroluminescent display devices, imaging devices such as image sensor devices, and electronic devices such as image input devices and fingerprint readers. In particular, the embodiments of the present invention can be suitably applied to large-sized liquid crystal display devices, and the like.

### DESCRIPTION OF REFERENCE CHARACTERS

2 substrate
3a1, 3a2 gate electrode
3b, 3c gate portion
3d auxiliary capacitance electrode
4 gate insulating film
5a1, 5a2 oxide semiconductor layer
6a, 6a1, 6a2, 7a, 7a1, 7a2 metal oxide layer
8a1, 8a2 source electrode
9a1, 9a2 drain electrode
10A1, 10A2 thin film transistor (TFT)
11 protective film
12 organic insulating film
13 transparent electrode
14 contact hole
80 gate/source intersection
90 gate/source contact portion
Cs1 auxiliary capacitance unit
100A semiconductor device

1. A semiconductor device, comprising a substrate and thin film transistors supported by the substrate,
wherein the thin film transistors each include an oxide semiconductor layer, a gate electrode, a source electrode, a drain electrode, and a metal oxide layer formed between at least either of the source electrode and the oxide semiconductor layer, or the drain electrode and the oxide semiconductor layer,
wherein the metal oxide layer includes a metal element that is included in at least one of the source electrode and the drain electrode, and
wherein a thickness T1 of the oxide semiconductor layer, a thickness T2 of the metal oxide layer, and a distance D between the source electrode and the drain electrode satisfy D≧1.56×(T2/T1)+0.75.

2. The semiconductor device according to claim 1, wherein the thickness T1 of the oxide semiconductor layer and the thickness T2 of the metal oxide layer further satisfy 0.21≦(T2/T1)≦0.57.

3. A semiconductor device, comprising a substrate and thin film transistors supported by the substrate,
wherein the thin film transistors each include an oxide semiconductor layer, a gate electrode, a source electrode, a drain electrode, and a metal oxide layer formed between at least either of the source electrode and the oxide semiconductor layer, or the drain electrode and the oxide semiconductor layer,
wherein the metal oxide layer includes a metal element that is included in at least one of the source electrode and the drain electrode, and
wherein a thickness T1 of the oxide semiconductor layer and a thickness T2 of the metal oxide layer satisfy 0.21≦(T2/T1)≦0.57.

4. The display device according to claim 1, further comprising an etching stopper layer formed so as to cover a channel region of the oxide semiconductor layer.

5. The display device according to claim 1, wherein said metal oxide layers are formed on the oxide semiconductor layer and the source electrode and the drain electrode are formed on the metal oxide layers.

6. The semiconductor device according to claim 4, further comprising an auxiliary capacitance unit,
wherein the auxiliary capacitance unit includes:
a gate portion formed of the same conductive film as a conductive film from which the gate electrode is formed;
a gate insulating film formed on the gate portion;
another oxide semiconductor layer formed on the gate insulating film; and
another metal oxide layer formed on said another oxide semiconductor layer,
wherein the drain electrode also covers said another metal oxide layer.

7. The display device according to claim 1, wherein the metal element is titanium, aluminum, chromium, copper, tantalum, molybdenum, or tungsten.

8. The display device according to claim 1, wherein the oxide semiconductor layer and said another oxide semiconductor layer include an In—Ga—Zn—O-type semiconductor.

9. A method of manufacturing a semiconductor device, comprising:
(A) forming a gate electrode on a substrate;
(B) forming a gate insulating film so as to cover the gate electrode;
(C) forming an oxide semiconductor layer on the gate insulating film;
(D) forming a source electrode and a drain electrode so as to be in contact with the oxide semiconductor layer;
(E) forming a protective film so as to cover the source electrode and the drain electrode; and
(F) forming a metal oxide layer on at least one of an area between the source electrode and the oxide semiconductor layer and an area between the drain electrode and the oxide semiconductor layer, by performing annealing,
wherein a thickness T1 of the oxide semiconductor layer, a thickness T2 of the metal oxide layer, and a distance D between the source electrode and the drain electrode satisfy D≧1.56×(T2/T1)+0.75.

10. The method of manufacturing a semiconductor device according to claim 9, wherein the thickness T1 of the oxide semiconductor layer and the thickness T2 of the metal oxide layer further satisfy 0.21≦(T2/T1)≦0.57.

11. (canceled)

12. The method of manufacturing the semiconductor device according to claim 9, further comprising, between the step (C) and the step (D), forming an etching stopper layer covering a portion of the oxide semiconductor layer to be a channel region.

13. The method of manufacturing a semiconductor device according to claim 12,
wherein the step (A) includes forming, on the substrate, another gate portion of the same conductive film as a conductive film by which the gate electrode is formed,
wherein the step (C) includes forming another oxide semiconductor layer formed so as to overlap the gate portion across the gate insulating film,
wherein the step (D) includes forming the drain electrode so as to also be in contact with said another oxide semiconductor layer, and
wherein the step (F) includes forming another metal oxide layer between said another oxide semiconductor layer and the drain electrode.

14-16. (canceled)

17. The display device according to claim 3, further comprising an etching stopper layer formed so as to cover a channel region of the oxide semiconductor layer.

18. The display device according to claim 3, wherein said metal oxide layers are formed on the oxide semiconductor layer and the source electrode and the drain electrode are formed on the metal oxide layers.

19. The semiconductor device according to claim 17, further comprising an auxiliary capacitance unit,
wherein the auxiliary capacitance unit includes:
a gate portion formed of the same conductive film as a conductive film from which the gate electrode is formed;
a gate insulating film formed on the gate portion;
another oxide semiconductor layer formed on the gate insulating film; and
another metal oxide layer formed on said another oxide semiconductor layer
wherein the drain electrode also covers said another metal oxide layer.

20. The display device according to claim 3, wherein the metal element is titanium, aluminum, chromium, copper, tantalum, molybdenum, or tungsten.

21. The display device according to claim 3, wherein the oxide semiconductor layer and said another oxide semiconductor layer include an In—Ga—Zn—O-type semiconductor.

22. The method of manufacturing the semiconductor device according to claim 10, further comprising, between the step (C) and the step (D), forming an etching stopper layer covering a portion of the oxide semiconductor layer to be a channel region.

23. The method of manufacturing a semiconductor device according to claim 22,
wherein the step (A) includes forming, on the substrate, another gate portion of the same conductive film as a conductive film by which the gate electrode is formed,
wherein the step (C) includes forming another oxide semiconductor layer formed so as to overlap the gate portion across the gate insulating film,
wherein the step (D) includes forming the drain electrode so as to also be in contact with said another oxide semiconductor layer, and
wherein the step (F) includes forming another metal oxide layer between said another oxide semiconductor layer and the drain electrode.
